(19) United States
(12) Patent Application Publication
(10) Pub. No.: US 2003/0227747 A1
(43) Pub. Date: Dec. 11, 2003

(54) Mechanism to assemble a fan in an electronic device

(76) Inventors: Chih-Hsiang Lee, Taoyuan City (TW); Guo-Ming Huang, Keelung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/164,185

(22) Filed: Jun. 5, 2002

(51) Int. Cl. H05K 7/20; G06F 1/20

(52) U.S. Cl. 361/695

(57) ABSTRACT

A mechanism to assemble a fan on an electronic device without using any screw is disclosed. The mechanism comprises: (a) a first extension of the housing, wherein in the first extension has a first hole thereon; (b) a first fastener fixed on the electronic device, wherein the first fastener is able to mount in the first hole on the first extension; (c) a second extension of the housing, wherein in the second extension is substantially away from the first extension and has a second hole thereon; and (d) a second fastener fixed on the electronic device, wherein the first fastener is able to mount in the first hole on the first extension and the second fastener is able to mount in the second hole on the second extension while the power input terminal is plugged in the socket.

### BACKGROUND OF THE INVENTION

1. Field of the Invention

The invention relates in general to a mechanism to assemble a fan in an electronic device, and more particular to a mechanism to assemble a fan in a server or a personal computer.

2. Description of the Related Art

As computers, such as central processing units, servers, and other similar types of electronic devices grow in speed and capacity, power consumed within the system per unit volume (power density) increases dramatically. Heat dissipation and ventilation became two important issues of computer system design. If the heat in a computer system cannot be properly and quickly transferred out of the enclosure, the computer system will malfunction resulting in serious damage.

Fans are installed to ensure that the components remain within their normal operating temperature ranges. The conventional manner for installing a fan is to use a large number of screws, which is not cost effective and takes long in assembling. Further more, screws are typically small in size and thus can be easily lost.

### SUMMARY OF THE INVENTION

It is therefore an object of the invention to provide an improved and simplified mechanism to assemble a fan on an electronic device without using any screw. The mechanism comprises: (a) a first extension of the housing, wherein in the first extension has a first hole thereon; (b) a first fastener fixed on the electronic device, wherein the first fastener is able to mount in the first hole on the first extension; (c) a second extension of the housing, wherein in the second extension is substantially away from the first extension and has a second hole thereon; and (d) a second fastener fixed on the electronic device, wherein the first fastener is able to mount in the first hole on the first extension and the second fastener is able to mount in the second hole on the second extension while the power input terminal is plugged in the socket.

It is another object of the invention to provide a mechanism to assemble a fan in an electronic device, which comprises: (a) a power input terminal connected to the fan, wherein the power input terminal is able to be plugged in a socket, which is fixed at the electronic device or other component of the electronic device; (b) a first extension of the housing, wherein in the first extension has a first hole thereon; and (c) a first fastener fixed on the electronic device, wherein the first fastener is able to mount in the first hole on the first extension while the power input terminal is plugged in the socket.

It is a further object of the invention to provide a mechanism to assemble a fan in an electronic device, which comprises: (a) a power input terminal connected to the fan, wherein the power input terminal is able to be plugged in a socket, which is fixed at the electronic device or other component of the electronic device; (b) a first extension of the housing, wherein in the first extension has a first hole thereon; (c) a first fastener fixed on the electronic device, wherein the first fastener is able to mount in the first hole on the first extension; (d) a second extension of the housing, wherein in the second extension is substantially away from the first extension and has a second hole thereon; and (e) a second fastener fixed on the electronic device, wherein the first fastener is able to mount in the first hole on the first extension and the second fastener is able to mount in the second hole on the second extension while the power input terminal is plugged in the socket.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 shows a mechanism to assemble a fan in a server, according to a preferred embodiment of the invention.

FIG. 2 shows a fan attached on a server base by the mechanism of assembling according to a preferred embodiment of the invention.

### DETAILED DESCRIPTION OF THE INVENTION

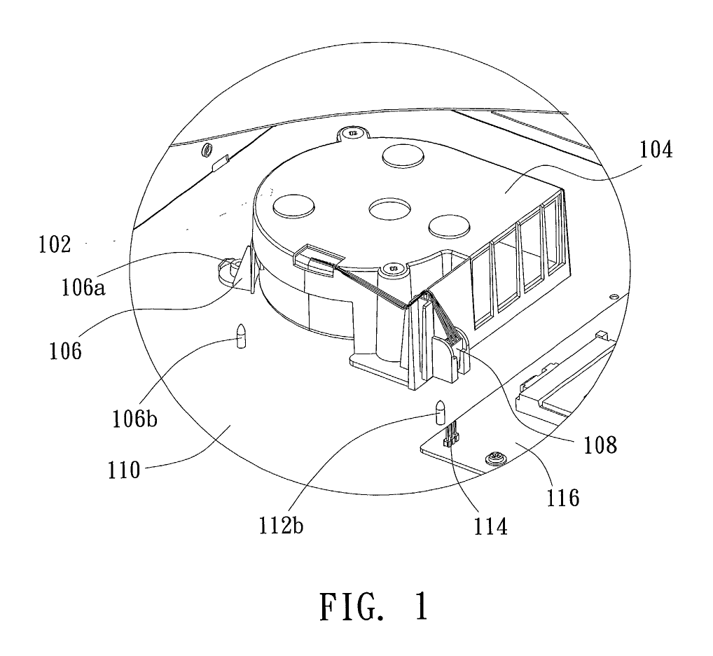

Referring to FIG. 1, a mechanism to assemble a fan in a server, according to a preferred embodiment of the invention is illustrated. The fan is numbered as 102. The housing 104 of the fan 102 has at least one extension. A fan 102 with two extensions, the first extension 106 and the second extension (not shown), is taken as an example for further illustration. The second extension is hidden from view by the power input terminal 108. The first extension 106 and the second extension are substantially away from each other to attach the fan 102 evenly at the server base 110. The first extension 106 and the second extension (not shown) respectively have the first hole 106a and the second hole (not shown). And on the server base 110,there are two fasteners, the first fastener 106b and the second fastener 112b, corresponding to the first hole 106a and the second hole (not shown). The two fasteners are preferably rivets fixed on the server base 110. The plug 114 for the power input terminal 108 of the fan 102 is preferably installed in the server 110 or other component such as a motherboard 116 of the server 110. While the power input terminal 108 is plugged in the socket 114, the first fastener 106b is able to mount in the first hole 106a and the second fastener is able to mount in the second hole.

The fan 102 as stated-above can be therefore attached on the server base 110 by the mechanism, including the first extension 106 with the first hole 106a, the second extension with the second hole (not shown), the corresponding fasteners fixed on the server base 110 and a pair of the power input terminal and plug. That is, with these three jointing points, the fan 102 can be firmly attached on the server base 110. By the mechanism of assembling, the fan 102 can be attached on the server base 110 without any screw and nut, and with the advantages of simple assembling and easy removing.

While the above description constitutes the preferred embodiment of the invention, it will be appreciated that the invention is susceptible to modification, variation, and change without departing from the proper scope or fair meaning of the accompanying claims. Modifications would include a mechanism with only one extension and one hole thereon. Together with the pair of the power input terminal and plug, the fan 102 can be firmly attached on the server base 110 with two jointing points.

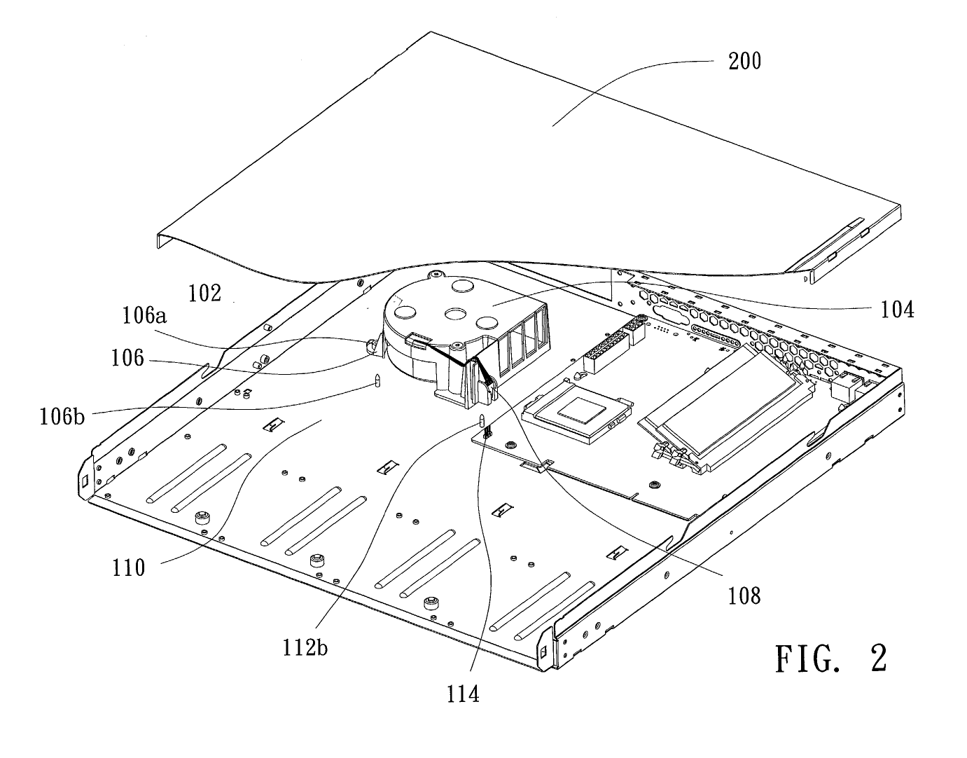

Referring to FIG. 2, a fan attached on a server base by the mechanism of assembling is shown. The thickness of the fan 102 is substantially the same as the thickness of the server, so that the top cover 200 can further fix the fan 102 in a horizontal direction.

While the embodiments are illustrated by attaching the fan on a server base, it is to be understood that the fan can be also attached on another electronic device such as a personal computer.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A mechanism to assemble a fan in an electronic device, wherein the fan has a housing, comprising:
a first extension of the housing, wherein in the first extension has a first hole thereon;
a first fastener fixed on the electronic device, wherein the first fastener is used to mount in the first hole on the first extension;
a second extension of the housing, wherein the second extension is substantially away from the first extension and has a second hole thereon; and
a second fastener fixed on the electronic device, wherein the second fastener is used to mount in the second hole on the second extension.

2. The mechanism according to claim 1, wherein the thickness of the fan is substantially the same as the thickness of the electronic device in a horizontal direction.

3. The mechanism according to claim 1, wherein the first fastener is a rivet.

4. The mechanism according to claim 1, wherein the second fastener is a rivet.

5. The mechanism according to claim 1, wherein the electronic device is a server.

6. The mechanism according to claim 1, wherein the electronic device is a personal computer.

7. A mechanism to assemble a fan in an electronic device, wherein the fan has a housing, comprising:
a power input terminal connected to the fan, wherein the power input terminal is used to be plugged in a socket, which is fixed on the electronic device or other component of the electronic device;
a first extension of the housing, wherein in the first extension has a first hole thereon; and
a first fastener fixed on the electronic device, wherein the first fastener is able to mount in the first hole on the first extension while the power input terminal is plugged in the socket.

8. The mechanism according to claim 7, further comprising:
a second extension of the housing, wherein in the second extension is substantially away from the first extension and has a second hole thereon; and
a second fastener fixed on the electronic device, wherein the first fastener is able to mount in the first hole on the first extension and the second fastener is able to mount in the second hole on the second extension while the power input terminal is plugged in the socket.

9. The mechanism according to claim 7, wherein the socket is plugged in a motherboard of the electronic device.

10. The mechanism according to claim 7, wherein the first fastener is a rivet.

11. The mechanism according to claim 7, wherein the second fastener is a rivet.

12. The mechanism according to claim 7, wherein the electronic device is a server.

13. The mechanism according to claim 7, wherein the electronic device is a personal computer.

14. The mechanism according to claim 7, wherein the thickness of the fan is substantially the same as the thickness of the electronic device in a horizontal direction.
